(19) United States
(12) Patent Application Publication
(10) Pub. No.: US 2007/0077730 A1
(43) Pub. Date: Apr. 5, 2007

(54) Method and device for extracting an electronic chip from a silicon wafer and transporting the chip to its installation location on an electronic device

(76) Inventor: Christophe Halope, Cannes (FR)

Correspondence Address: JAMES C. LYDON, 100 DAINGERFIELD ROAD, SUITE 100, ALEXANDRIA, VA, 22314, US

(21) Appl. No.: 11/529,317

(22) Filed: Sep. 29, 2006

(30) Foreign Application Priority Data
Sep. 30, 2005 (FR) 0510000

(51) Int. Cl. H01L 21/30; H01L 21/46

(52) U.S. Cl. 438/455; 438/458

(57) ABSTRACT

The invention concerns a method for extracting chips (20) from a silicon wafer (10) and for transferring each chip on an electronic device including the following steps:
Extracting the good chips from the silicon wafer (10) and transferring them on a roll-up adhesive film (28) so that the chips are spaced out by a certain distance,
Transferring the chips (20) from the roll-up film (28) directly and continuously on contacts (46, 48 or 58, 60) of the electronic device.

### TECHNICAL FIELD

The present invention concerns the installation of the electronic chip on RFID type radiofrequency labels and contactless smart cards and specifically concerns a method and device for extracting an electronic chip from a silicon wafer and transporting the chip to its installation location on an electronic device.

### BACKGROUND ART

Electronic chips or integrated circuits designed for the manufacture of electronic circuits for radiofrequency identification (RFID) devices such as contactless smart cards and radiofrequency labels must be connected to the antenna of the RFID device. The electronic chips are delivered by the chip suppliers on silicon slices known as wafers. These wafers that group several hundred integrated circuits are generally delivered glued to an adhesive sheet. The wafer is cut out beforehand so that the chips are detached from one another while remaining glued together on the adhesive sheet. Each chip is then extracted from the silicon wafer so that it can be directly positioned on the contacts of the circuit's antenna.

The methods used to connect chips to the antennas of an electronic device including a chip and antenna are based on the “Flip Chip” assembly technique. This technique is characterized by a direct connection of the chip's active side onto the antenna and its substrate, in contrast to the older “Wire Bonding” wiring technique described earlier, which consisted in bonding the chip's passive side to the substrate and wiring it to the antenna.

The “Flip Chip” assembly technique according to a patented method of the applicant includes the steps consisting in:
positioning the chip provided with contacts made of a non-deformable material on the antenna support so that the contacts are facing the contacts of the antenna, and
exerting a pressure on the chip so that the chip's contacts deform the antenna support and the antenna contacts as a result of the pressure, the support and the antenna contacts maintaining their deformation after the exerted pressure has been released, thus allowing a maximum contact surface to be obtained between the chip's contacts and the antenna contacts.

The method also includes an additional step which consists in placing adhesive dielectric material directly on the active side of the chip between the contacts, prior to the chip positioning step, so as to maintain the chip in a fixed position relative to the support.

For implementing this method, several types of machines exist depending on whether the chips are supplied with their active side against the adhesive or otherwise. When the chips present the passive side on top of the silicon wafer, the extraction and chip transfer machine presents an arm equipped with a flexible suction cup, which detaches the chip from the adhesive by suction and thanks to a tip located on the side of the adhesive that presses on the location of the chip to be extracted. The arm is equipped with cameras to view the exact location of the electronic device on which the chip must be positioned. According to the measurements made by the cameras, the position of the arm is adjusted. Once extracted, the chip is transported towards the electronic device and presented by the arm directly on the antenna contacts designed to come into contact with the chip's contacts. This method of extracting the chip and positioning it on the circuit requires a series of operations carried out by the machine arm, which performs a to-and-fro movement. Furthermore, the electronic devices assembled in a roll, such as a web, move as the transfer operation progresses. Because of the measurements that need to be made by the cameras and the adjustment time of the arm, the web moves by successive and discontinuous advances. Another type of machine is adapted to extract the chips from a silicon wafer in which the passive side of chips is glued on the adhesive. This type of machine features two arms so that the chip extracted from the silicon wafer by the first arm is turned over before being held by the second arm, which transports the chip to its final location on the electronic chip. Just as for the first type of machine, cameras are used to view the antenna contacts on which the chip must be connected so that the position of the second arm can be adjusted with respect to the position of the RFID device placed on the web. The rates obtained by these two types of machines do not exceed 40,000 units per hour due to the time required for to-and-fro movements of the machine arms and the time required for adjusting the position of the chip with respect to the electronic devices.

### SUMMARY OF THE INVENTION

This is why, the object of the invention is to mitigate these drawbacks by providing a method for extracting the chip from a silicon wafer and transferring said chip up to the contacts of an electronic device, and do this continuously so that rates greater than those of traditional chip transfer machines are obtained while ensuring the sturdiness and accuracy of the connection of the chip on the contacts.

The purpose of the invention is thus a method for extracting chips from a silicon wafer and transferring each chip on an electronic device including the following steps:
Extracting the good chips from the silicon wafer and transferring them on a roll-up adhesive film so that the chips are spaced out by a certain distance,
Transferring the chips from the roll-up film directly and continuously on contacts of the electronic device.

Another object of the invention is a device for extracting electronic chips from a silicon wafer including systems to transport the chip from the wafer on a roll-up adhesive film and means to directly and continuously transfer the chip from the roll-up film to contacts of an electronic device.

### BRIEF DESCRIPTION OF THE DRAWINGS

The purposes, objects and characteristics of the invention will become more apparent from the following description when taken in conjunction with the accompanying drawings in which:

FIG. 1 represents a silicon wafer equipped with precut chips, FIG. 2 represents the extraction machine for chips according to the invention, FIG. 3 represents a web for RFID type electronic device supports, FIG. 4 represents a cross-section of the antenna support after the chip positioning step, FIG. 5 represents an antenna for RFID type electronic device in UHF, FIG. 6 represents an antenna for an RFID type electronic device in UHF after laser cutting, FIG. 7 represents an antenna for an RFID type electronic device in UHF after the chip positioning step.

### DETAILED DESCRIPTION OF THE INVENTION

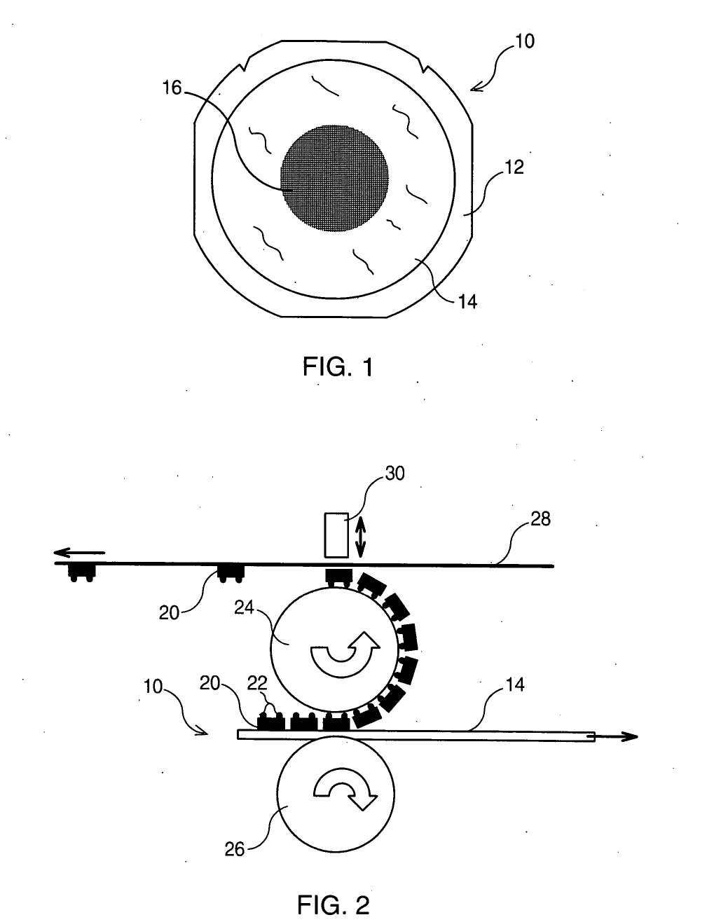

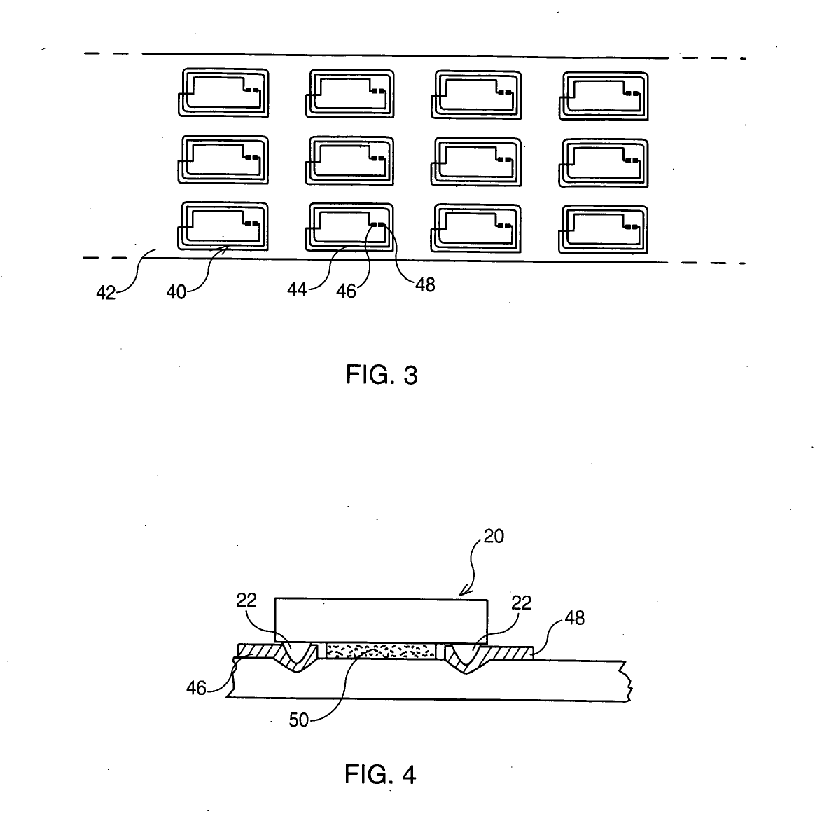

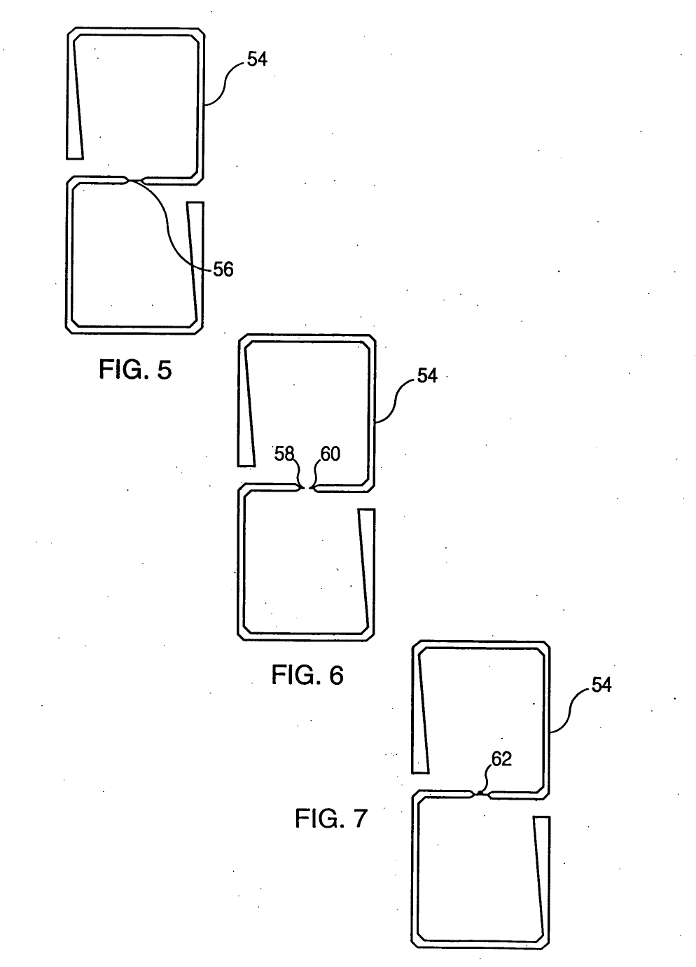

According to FIG. 1, the silicon wafer 10 or “wafer” is shown in front view. It includes a support 12 which maintains a flexible adhesive 14. The chips or integrated circuits are glued on the adhesive 14 in the form of a disk 16. The chips have been precut so that they are independent of one another. The installation technique considered here is characterized by a direct connection of the active side of the chip on the antenna contacts. This assembly technique is known as the “Flip Chip” assembly technique and consists in placing a ball of conductive material commonly referred to as “bump”, usually made of gold, on each of the metal connections of the chip so as to form one or more contacts of preferably non-deformable material.

FIG. 2 is a diagrammatic view of the extraction step of chips from the silicon wafer. The wafer 10 viewed from side presents chips glued 20 with their passive side on the adhesive 14. The contacts 22 located on the active side of chips 20 are thus on the unconnected side of the chip opposite the side of the chip glued to the adhesive. Only the good chips 20 will be selected for being transferred to electronic devices. As a result, certain chips are declared bad and must not be used. To select only the good chips, a method consists in using an adhesive 14 sensitive to ultraviolet radiation. In this way, only the location of good chips is exposed to light in order to desensitize the adhesive at the location where the chip is glued. Another method consists in using the computer file provided with the silicon wafer, which helps locate the location of bad chips.

The chips 20 are extracted from the wafer 10 by means of a suction wheel 24. The wafer 10 is positioned in such a manner that the wheel 24 is aligned with one line of chips of the wafer 10. The wheel 24 is installed on a fixed shaft driven in rotation by a motor and has a suction system over its entire periphery. The wafer 10 moves so that the wheel 24 aligned along a line of the chip takes off the chips 20 by suction, which creates a force that is sufficient to remove the good chips from the adhesive 14 and keeping them in contact on the periphery of the wheel 24, their active side against the wheel. The contact of the wheel 24 with the chips of the wafer 10 is ensured by an auxiliary idler wheel 26 installed on a fixed shaft. The chips 20 held on the rotating wheel 24 are then transferred to an adhesive film 28 thanks to a transfer support system 30, the film 28 being set in motion by means of a motor at an adjustable speed. The transfer support system includes a tip with a flattened point having the chip's size that is located near the film 28 and in line with the wheel 24. The transfer support system rests against the film 28 on the non-adhesive side of the film 28 thanks to a translation motion so that the adhesive of the film 28 comes in contact with the chips 20 of the wheel 24, one by one. The chips are thus transferred one by one from the wheel 24 to the adhesive 28 and are placed at a desired distance from one another according to the film 28 transfer speed. The film 28 is preferably parallel to the adhesive 14 of the silicon wafer 10 so that the chips perform half a rotation of the wheel 24 between the time when they are taken from the silicon wafer 10 and the time when they are transferred onto the film.

The spacing between the chips placed on the film 28 is thus managed by adjusting the film speed. The control of this speed thus helps take up the free spaces left between the chips and the wheel 24 resulting from bad chips left on the wafer 10. The adhesive film 28 carrying the chips can be stored in a roll before being integrated with the method for transferring chips on electronic devices.

According to an alternate embodiment of the chips extraction step, the wheel 24 takes off several rows of chips 20 simultaneously over its periphery and transfers them to as many adhesive films.

The next step that includes the transfer of chips on electronic devices is independent from the step consisting in extracting the chips from the silicon wafer as described earlier. Each radiofrequency (RFID) identification type electronic device features an antenna and a chip connected together, the shape of the antenna depending on the application, the range of frequencies used, etc. Prior to the step of connecting the chip, the antenna is made on a support of deformable material such as fibrous material, preferably made of paper, by printing with conductive ink such as ink loaded with silver or carbon particles. The antenna can be made, for example, by screen printing, flexography, rotogravure, offset printing or inkjet printing. The antenna support is in the form of a roll to enable the production of large quantities of electronic devices, which will then be cut out. FIG. 3 shows a web 42 used to support the RFID type electronic devices 40 and featuring 13.56 MHz type antennas 44 such as those defined in the standards ISO 14443 and 15693 capable of being connected to a chip thanks to contacts 46 and 48. At this manufacturing step, as mentioned below in the description of a second embodiment of the invention, the contacts 46 and 48 may not be formed, that is to say there are then connected together by the same material than the one they are made of. The film 28 including the chips is placed parallel to the web 42 so that the side of the film 28 featuring the chips 20 and the side of the web 42 featuring the antennas are facing each other. The web 42 advances in a continuous motion while the film 28 including the chips 20 unwinds as the chips are transferred. Adhesive material is applied on the chip between the contacts of the chip before it is placed on the antenna. The adhesive material used is preferably an epoxy resin or a cyanoacrylate glue.

Once the adhesive material 50 has been applied, the chip is positioned on the antenna support in a manner that the contacts of the chip are in contact with the contacts 46 and 48 of the antenna 40. The adjustment of contacts of the chip with those of the antenna is done by means of a camera located near the chip to be positioned. FIG. 4 represents a cross sectional view of the chip-antenna assembly.

Pressure is exerted on the chip 20 so that the contacts 22 of the chip 20 cause a deformation of the support and contacts 46 and 48 of the antenna 40 as shown in FIG. 4. The latter are then deformed so as to form an imprint whose inner surface exactly matches the outside surface of the contacts. Thanks to an intimate contact between the connection pads, the contact area between the chip's contacts 22 and the contacts 46 and 48 of the antenna 40 is maximum. The material which makes up the antenna support is preferably deformable and non-elastic such as conductive ink of the antenna's contacts 46 and 48. As such, these two materials tend not to return to their original shape even when the pressure is released. This is particularly true when the material of the support is a fibrous material such as paper. As a result of the pressure, the adhesive dielectric material 50 spreads and covers the entire surface of the chip between the contacts. It thus enables the mechanical assembly between the chip 20 and the antenna support—and thereby the electric contact between the chip and the antenna—to be reinforced.

According to a variant of the transfer step of the chip on the RFID type electronic chip, the antenna's contacts are created at the time of the transfer. This variant relates to RFID type electronic devices operating in all frequency ranges such as 13.56 MHz frequency defined in ISO 14443 and 15693 standards in the very high frequency range (frequency in the 860-960 MHz range and frequency of 2.45 GHz according to the ISO 18001 standard). An example of an antenna used for these frequency ranges is shown in FIG. 5. The antenna 54 has two wires connected together by a narrower portion 56 and, as in the first embodiment, the antennas are placed side by side to form a web similar to the one shown in FIG. 3. The web advances in a continuous motion whereas the film 28 including the chips 20 unwinds as the chips are transferred. Just before placing the chip on the antenna, a laser cutout is made to cut the portion 56 and create two contacts 58 and 60 disconnected from one another. The chip is then positioned in the same way as in the first embodiment. The chip-antenna assembly shown in FIG. 4 is also applicable to the assembly of chip 62 on the contacts 58 and 60 of the antenna 54. Adhesive material is applied on the chip between the contacts of the chip before being placed on the antenna. Once the adhesive material has been applied, the chip is positioned on the antenna support in such a manner that the contacts of the chip are opposite the contacts 58 and 60 of the antenna 54. Pressure is exerted on the chip 62 so that the contacts of the chip 62 cause deformation of the antenna support and contacts 58 and 60 of the antenna 54. The latter are then deformed so as to form an imprint whose inner surface exactly matches the outside surface of the contacts. Thanks to the intimate contact between the connection pads, the contact area between the chip's contacts and the contacts 58 and 60 of the antenna 54 is maximum. The material which makes up the antenna support is preferably deformable and non-elastic such as conductive ink of the contacts 58 and 60. As such, these two materials do not tend to return to their original shape, even when the pressure is released. This is particularly true when the material of the support is a fibrous material such as paper. As a result of the pressure, the adhesive dielectric material spreads and covers the entire surface of the chip between the contacts. It thus enables the mechanical assembly between the chip 62 and the antenna support—and thereby the electrical contact between the chip and the antenna—to be reinforced. As a result of the pressure, the adhesive dielectric material spreads and covers the entire surface of the chip between the contacts. Unlike the first embodiment, laser cutting and formation of the antenna contacts immediately before positioning the chip, helps avoid an adjustment made using a camera.

The transfer method of chips, owing to the continuous movement of the web and simplified adjustment, helps obtain high output rates in the order of 100,000 devices per hour.

The transfer method of the chip, as described according to the invention, applies to all types of electronic devices such as an electric circuit featuring two contacts capable of receiving an integrated circuit or a chip.

1-11. (canceled)

12. A method for extracting chips from a silicon wafer and for transferring each chip onto an electronic device, comprising the following steps:
extracting good chips from a silicon wafer and transferring them on a roll-up adhesive film so that the chips are spaced from one another by a certain distance,
transferring the chips from the roll-up film directly and continuously onto contacts of the electronic device.

13. The method of claim 12, wherein the electronic device is a radiofrequency device having an antenna.

14. The method of claim 13, wherein contacts of said antenna are created immediately before the transfer step of the chip by laser cutting of the antenna.

15. The method of claim 12, wherein said chips are extracted from the silicon wafer and transferred to said film by a wheel.

16. The method of claim 15, wherein said wheel is installed on a fixed shaft and fitted with a suction system over its entire periphery, which creates a sufficient force to keep the chips in contact on the periphery of the wheel, with their active side against the wheel.

17. The method of claim 15, wherein said chips are transferred from the wheel to the film by a transfer support system.

18. The method of claim 17, wherein said transfer support system comprises a tip with a flattened point adapted to press against the film so that the adhesive of the film is put in contact with the chips of the wheel one after the other.

19. The method of claim 12, wherein a plurality of electronic devices are placed on a web that advances in a continuous motion while the film carrying the chips unwinds as the chips are transferred at an adjustable speed.

20. The method of claim 12, wherein the chip transfer step includes the following steps:
positioning the chip provided with contacts on the antenna support so that said contacts of the chip are facing the contacts of the antenna, and
exerting a pressure on the chip so that the contacts deform the antenna support and the antenna contacts as a result of the pressure, the support and the antenna contacts maintaining their deformation after the exerted pressure has been released, thus enabling a large contact surface to be obtained between the contacts of the chip and the antenna contacts.

21. The method of claim 12, wherein an adhesive dielectric material is placed between the contacts of said chip, before the chip is positioned, so as to maintain said chip in a fixed position relative to the antenna support.

22. A device for extracting electronic chips from a silicon wafer, comprising
means for transporting the chip from the wafer on a roll-up adhesive film and
means for directly and continuously transferring the chip from the roll-up film to contacts of an electronic device.
